(19) United States
(12) Patent Application Publication
(10) Pub. No.: US 2003/0149926 A1
(43) Pub. Date: Aug. 7, 2003

(54) Single scan chain in hierarchiacally bisted designs

(76) Inventor: Krishna B. Rajan, Newark, CA (US)

Correspondence Address: BLAKELY, SOKOLOFF, TAYLOR & ZAFMAN LLP, Seventh Floor, 12400 Wilshire Boulevard, Los Angeles, CA, 90025-1030, US

(21) Appl. No.: 10/072,342

(22) Filed: Feb. 7, 2002

(51) Int. Cl. G01R 31/28

(52) U.S. Cl. 714/726

(57) ABSTRACT

Disclosed are novel methods and apparatus for efficiently providing a single scan chain design for hierarchically BISTed designs. In an embodiment, a method of providing a single scan chain of a chip is disclosed. The method includes: selecting a TOP chain of the chip, the chip being divided into a plurality of embedded logic test (ELT) blocks; bypassing periphery flops of the plurality of ELT blocks; selecting a single scan chain of all ELT blocks of the chip; and inserting the single scan chain of all ELT blocks of the chip into the TOP chain of the chip.

### FIELD OF THE INVENTION

The present invention relates to the field of circuit testing and, more specifically, to providing a single scan chain in hierarchically implemented built-in-self-test (BIST) designs.

### BACKGROUND OF INVENTION

As the complexity of integrated circuits (ICs) increases and access to their internal circuit nodes becomes harder, properly testing such devices has become a major bottleneck during their prototyping, development, production, and maintenance. As a result, designs with BIST implementation have become commonplace. In a BIST implementation, circuitry (which is intended solely to support testing) is included in an IC and/or in a system including ICs.

Currently, many application specific integrated circuits (ASICs) implement logic BIST using available tools, such as those provided by LogicVision, Inc., of San Jose, Calif. Logic BIST is a very important reliability, availability, and serviceability (RAS) feature and can play a vital role in testing for the quality of ASICs, boards, and systems. As the number of gates on ICs increase, testing becomes even more important because of the existence of many additional possible failure points. At the same time, logic BIST implementation of such devices becomes harder on the larger designs.

To alleviate this problem, electronic design automation (EDA) tool providers offer a technique called hierarchical BIST, wherein a design is divided into several partitions and each partition is independently BISTed. Each of these partitions is also referred to as an embedded logic test (ELT) block. Hierarchical BIST is especially useful with larger designs (e.g., over two million gates).

A hierarchically BISTed design typically has one or more ELT blocks, and one TOP-level block that BISTs logic outside the ELT blocks (such as boundary scan logic, IO pads, functional flops in IO area, and any other loose logic at TOP). In order to be able to independently test each ELT block, each ELT block is isolated by a ring of periphery flops (a.k.a. isolation flops) to form one or more periphery scan chains. Accordingly, each ELT block can be configured into a single scan chain, multiple scan chains, and/or logic BIST chains.

The ELT blocks operate in two modes, namely, internal mode and external mode. In the internal mode, all the flops inside the ELT can be configured as a single scan chain. The periphery flops (chains) of such an ELT block are put in internal mode such that they do not capture values arriving at the flops' D-inputs to avoid capture of unknown values arriving at the given ELT block. When the ELT block is in external mode (by for example putting TOP logic into internal mode), the periphery flops in the ELT block can serve as observation (capture) flops for values driven by the TOP logic, and control flops for driving values to the TOP logic.

To provide access to BIST functionality on a chip, a test access port (TAP) may be utilized. TAP can be a general-purposed port that can provide access to test support functions built into a component. Further information on TAP may be found in IEEE Standard Test Access Port and Boundary-Scan Architecture, IEEE Std 1149.1-1990 (includes IEEE Std 1149.1a-1993), Chapter 3, entitled “The Test Access Port” which is hereby incorporated herein for all purposes.

One of the current problems with hierarchical BIST is that the present day architectures (and tools) do not allow for implementation of a single scan chain on, for example, an entire chip. Single scan chain feature is, however, very useful for chip, board, and system debugging purposes.

### SUMMARY OF INVENTION

The present invention includes novel methods and apparatus to efficiently provide a single scan chain in hierarchically BISTed designs. In an embodiment, a method of providing a single scan chain of a chip is disclosed. The method includes: selecting a TOP chain of the chip, the chip being divided into a plurality of embedded logic test (ELT) blocks; bypassing periphery flops of the plurality of ELT blocks; selecting a single scan chain of all ELT blocks of the chip; and inserting the single scan chain of all ELT blocks of the chip into the TOP chain of the chip.

In another embodiment, the bypassing is accomplished by use of a plurality of multiplexers. In yet another embodiment, the method further includes selecting a plurality of blocks within a test access port (TAP) block.

In a further embodiment an apparatus is disclosed. The apparatus comprising: a first selector to select a TOP chain of a chip, the chip being divided into a plurality of embedded logic test (ELT) blocks; a bypassing mechanism to bypass periphery flops of the plurality of ELT blocks; a second selector to select a single scan chain of all ELT blocks of the chip; and a combiner to combine the single scan chain of all ELT blocks of the chip with the TOP chain of the chip, wherein the apparatus provides a single scan chain of the chip.

### BRIEF DESCRIPTION OF DRAWINGS

The present invention may be better understood and it's numerous objects, features, and advantages made apparent to those skilled in the art by reference to the accompanying drawings in which:

FIG. 1 illustrates an exemplary hierarchically BISTed design with two ELT blocks in accordance with an embodiment of the present invention;

FIG. 2 illustrates an exemplary hierarchically BISTed design with one ELT block in internal mode in accordance with an embodiment of the present invention;

FIG. 3 illustrates an exemplary hierarchically BISTed design with another ELT block in internal mode in accordance with an embodiment of the present invention;

FIG. 4 illustrates an exemplary hierarchically BISTed design with the TOP block in internal mode and two ELT blocks in external mode in accordance with an embodiment of the present invention; and

FIG. 5 illustrates an exemplary hierarchically BISTed design with the TOP and ELT blocks in internal mode to provide a single scan chain of a whole chip in accordance with an embodiment of the present invention.

The use of the same reference symbols in different drawings indicates similar or identical items.

### DETAILED DESCRIPTION

In the following description, numerous details are set forth. It will be apparent, however, to one skilled in the art, that the present invention may be practiced without these specific details. In other instances, well-known structures and devices are shown in block diagram form, rather than in detail, in order to avoid obscuring the present invention.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

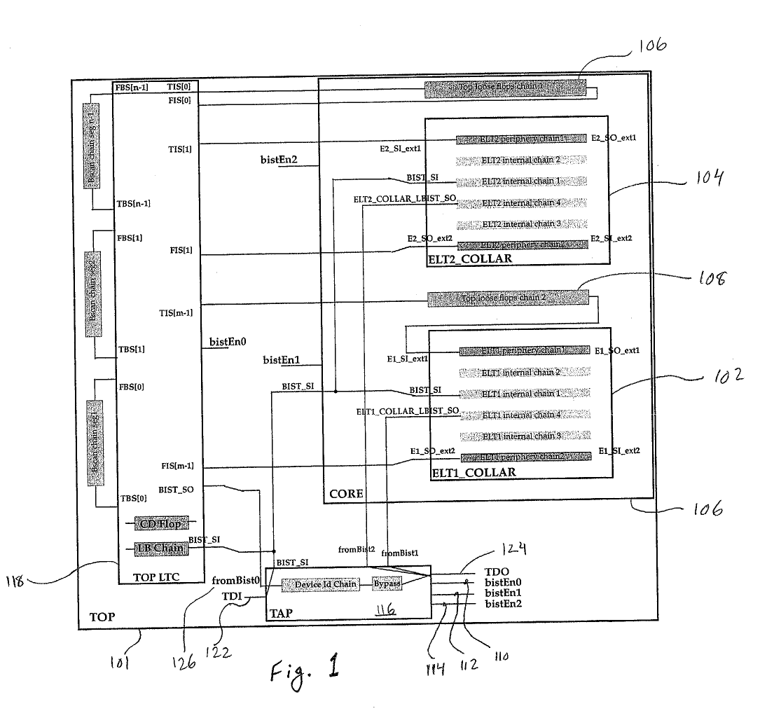

FIG. 1 illustrates an exemplary hierarchically BISTed design with two ELT blocks within a TOP block 101 in accordance with an embodiment of the present invention. In FIG. 1, ELT1 102 and ELT2 104 blocks are inside a top-level logic block (TLB) called CORE 106. The CORE module 106 also includes loose flops 106 and 108 that are coupled as one or more internal scan segments of the TOP logic (associated with the TOP block 101). Moreover, any functional flops in the input output (IO) area (not shown) may show up as additional internal scan segments of the TOP logic. When a bistEn0 signal 110 is selected, the TOP block 101 is put into internal mode and ELT blocks into external mode. Also, when a bistEn1 signal 112 is selected, the ELT1 block 102 is put into internal mode. Similarly, when a bistEn2 signal 114 is selected, the ELT2 block 104 is put into internal mode.

The TOP block 101 also includes a TAP block 116 and a TOP LTC block 118. It is envisioned that the TAP block 116 is a general-purpose test access port to test support functions built into a component. In some embodiments, the TAP block 116 may be compliant with IEEE Standard Test Access Port and Boundary-Scan Architecture, IEEE Std 1149.1-1990 (includes IEEE Std 1149.1a-1993). The TOP LTC block 118 may be a general logic test controller (LTC) such as those employed to provide control functionality to ELT blocks, for example. It is envisioned that the TAP block 116 has a number of inputs and outputs including a test data input (TDI) 122, a test data output (TDO) 124, the bistEn0 through bistEn2 signals (110-114), and a fromBist0 signal 126.

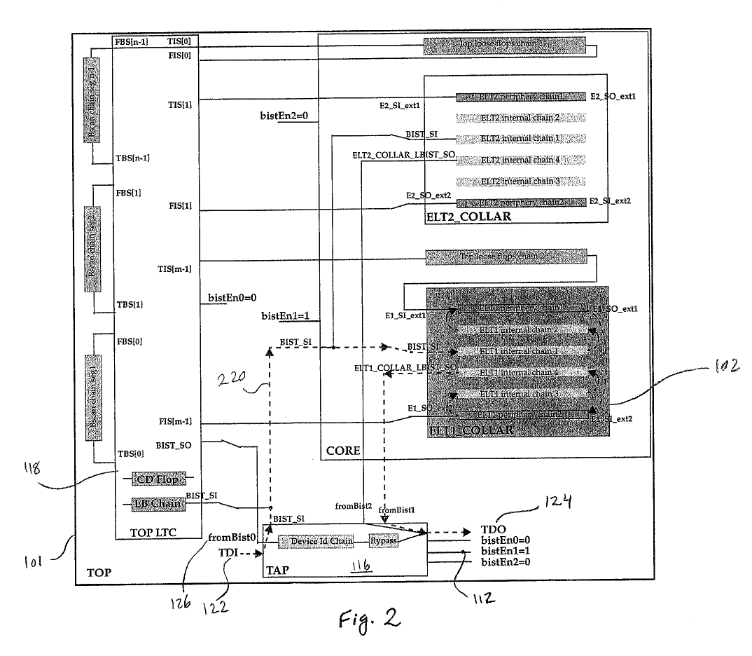

FIG. 2 illustrates an exemplary hierarchically BISTed design with one ELT block in internal mode in accordance with an embodiment of the present invention. FIG. 2 shows the view of the design when the ELT1 102 block is selected and put into internal single chain mode by, for example, activating the bistEn1 signal 112. It is envisioned that this function may be performed through an instruction issued to the TAP 116. This single chain is a concatenation of all flops (including periphery flops) in the ELT1 block. FIG. 2 shows the single chain of ELT1 block 102 by the dashed line 220 starting at the TDI 122 and ending at the TDO 124.

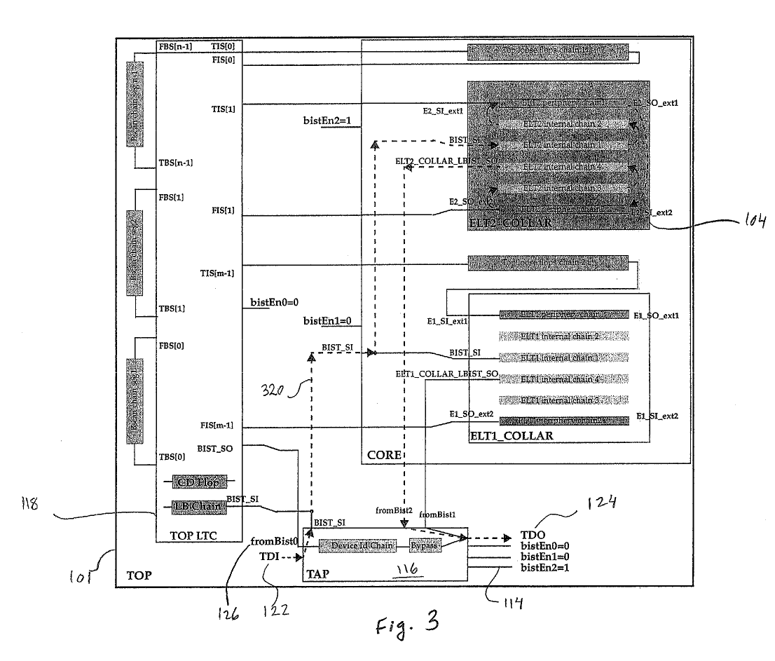

FIG. 3 illustrates an exemplary hierarchically BISTed design with another ELT block in internal mode in accordance with an embodiment of the present invention. In FIG. 3, the ELT2 block 104 is selected and put into internal single chain mode by, for example, activating the bistEn2 signal 114 through an instruction to the TAP 116. This single chain is a concatenation of all flops (including periphery flops) in the ELT2 block 104. FIG. 3 shows the single chain of ELT2 block 104 by the dashed line 320 starting at the TDI 122 and ending at the TDO 124.

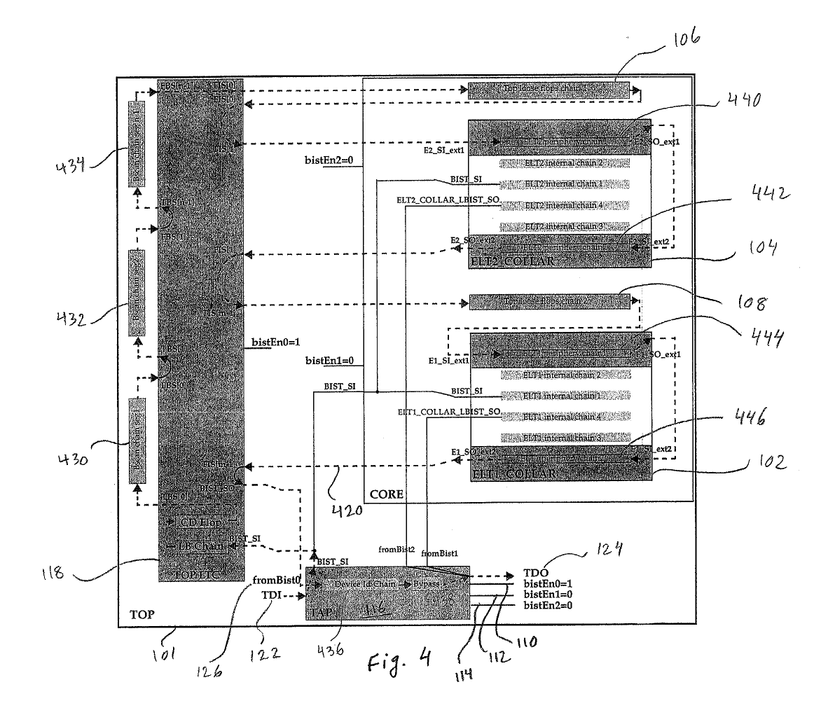

FIG. 4 illustrates an exemplary hierarchically BISTed design with the TOP block in internal mode and two ELT blocks in external mode in accordance with an embodiment of the present invention. In FIG. 4, the TOP block 101 is selected and put into internal single chain mode by activating bistEn0 110, for example, through an instruction issued to the TAP 116. In this mode, ELT1 102 and ELT2 104 blocks are put into external mode (for example by setting bistEn1 and bistEn2 signals (112 and 114) to 0) and only their periphery flops are picked up as part of the TOP chain. This single chain is a concatenation of all the flops (including boundary scan flops 430-434, device ID flops 436 within the TAP 116, a bypass flop 438 within the TAP 116, functional flops in 10 pad area (not shown), and any loose flops outside ELT blocks) in the TOP block 101 and periphery flops 440-446 in the ELT1 102 and ELT2 104 blocks. FIG. 4 shows the single chain of the TOP block 101 by the dashed line 420 starting at the TDI 122 and ending at the TDO 124.

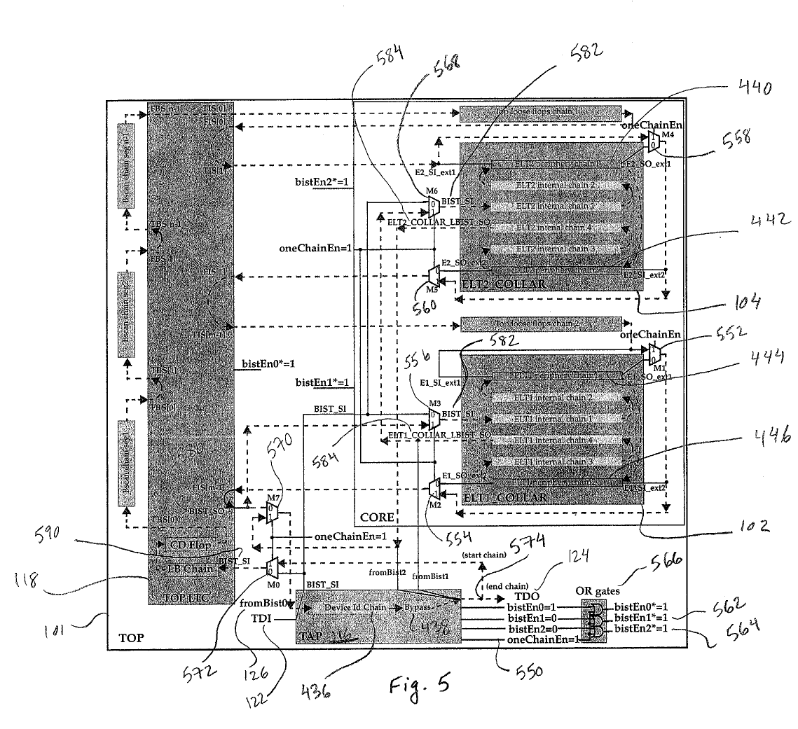

FIG. 5 illustrates an exemplary hierarchically BISTed design with the TOP and ELT blocks in internal mode to provide a single scan chain of a whole chip in accordance with an embodiment of the present invention. One approach taken to achieve the chip single chain is to first select the TOP chain but avoid (i.e., bypass) picking up the periphery flops from the ELT blocks and then to insert the single chain of all ELT blocks into the TOP chain. This can be done by first putting the TOP block 101 into internal mode by, for example, loading the appropriate instruction into the TAP block 116 (similar to that discussed with respect to FIG. 4).

It is envisioned that a user index register (IR) bit can be set to indicate a chip single chain mode. The user IR bit can activate the oneChainEn signal 550 from the TAP block 116. In this mode, the entire chain of both ELT1 and ELT2 blocks (102 and 104) are picked up instead of the periphery flops 440-446 of the ELT1 and ELT2 blocks (102 and 104) for the TOP chain. This can be done by, for example, first bypassing the original periphery flops (440-446) of the ELT1 and ELT2 blocks (102 and 104) in the TOP chain with muxes M1, M2, M4, and M5 (552-560). With this, all the non-ELT flops of the TOP logic in the chain are picked up.

Since the oneChainEn signal 550 is active in this situation, bistEn1* and bistEn2* are also activated (due to the OR gates 566) and the ELT1 and ELT2 blocks (102 and 104) are put into internal modes as well. Accordingly, in certain embodiments, to provide a single scan chain for the entire design, it is desired to have all ELT blocks and TOP block to be selected and put in internal mode. For this, it is envisioned that the respective bistEn signals be activated. First, all the bistEn# ports from the TAP that correspond to activating the ELT blocks need to be determined (avoid the bistEn corresponding to memory BIST). The TOP block is generally enabled through bistEn0. Once these ports/nets are identified, the signals can be intercepted with OR gates (such as 566 of FIG. 5). The other input of the OR gate can be driven by a oneChainEn port from the TAP which helps enable all ELT blocks and TOP block in internal mode once in chip single chain mode.

With the help of muxes M3 and M6 (556 and 568), all flops (including periphery flops 440-446) in the ELT1 and ELT2 blocks (102 and 104) can be picked up and inserted into the TOP chain. Finally, the flops device ID 436 and bypass 438 are picked up into the chip single chain through a mux M7 570. An optional mux M0 572 can be used for re-circulating the data back to the scan chain for restoring the pre-scandump state of the design after scandump. FIG. 5 shows the single chain of the chip by the dashed arrow line 520, starting at a start chain sign 574 and ending at the TDO 124.

Accordingly, in certain embodiments of the present invention, it is desirable to determine the points most suitable for bypassing and inserting flops/segments to build the chip single scan chain are determined. In particular, it is desirable to first identify the scan-in/scan-out ports of the periphery segments and to bypass them. In certain embodiments, this can be done by referring to a configuration file of a design tool, for example. If the design does not have any functional flops outside its ELT blocks, then bypassing each periphery segment is not required. Instead, the muxes can be placed between TIS[x] and FIS[x], where TIS[x] feeds FIS[x] during single chain mode.

It is also envisioned that in given embodiments, where there are loose flops in the design, the scan chain segment connected between TIS[x] and FIS[x] could be of three scenarios: (A) it can comprise only TOP-logic loose flops and no periphery flops; (B) it can comprise only periphery flops of ELT blocks; and (C) it can comprise a combination of TOP-logic loose flops and periphery flops of ELT blocks. In scenario (A), no bypassing or change is required (for example, chain segment connected between TIS[0] and FIS[0]). In scenario (B), it is efficient to place the bypass mux between TIS[x] and FIS[x] as opposed to placing muxes for each periphery segment placed between them (for example, one may use one mux between TIS[1] and FIS[1] instead of the two muxes M4 and M5 of FIG. 5). In scenario (C), one may not place a mux between TIS[x] and FIS[x] but instead can place it at the periphery segments itself. However, a further improvement can be achieved in these cases once the order in which the periphery segments are concatenated is known (for example, instead of the two muxes M1 and M2 of FIG. 5, a single mux could be placed between the output of the top loose flops chain 2 and FIS[m−1]).

The above reductions can be done in situations where the configuration of loose flops and periphery segments between a TIS[x] and FIS[x] are known. In an embodiment, the configuration may not be known ahead of time and as a result one may resort to alternative approaches such as bypassing each periphery segment one at a time. The bypassing itself could lead to slow down of scan shift operations since many levels of muxes may be present between the scanout of previous segment to the scan-in of the next segment. Generally, scan shift is a mechanism to obtain desired values at flip-flop outputs. It can be achieved by holding the scan enable control signal of the flop to an active value, provide the desired value at the scan input of the flop, and provide one clock cycle. Scanout generally corresponds to the output port of the flop for a scan value. And, scan-in generally corresponds to the input port of the flop for a scan value.

It is envisioned that one solution is to add a pipeline flop on the bypass path at the input of these muxes to speed up scan shift of this chip single chain. An alternative is to perform an initial run without any customization to determine the scan chain order for the TOP chain and identify only the relevant scan-in and scan-out ports of the periphery segments to bypass, and then rerun a simulation tool with the new port information to minimize the number of muxes added.

The next step is to identify the points where concatenation of all the ELT single chains are to be inserted. In certain embodiments, the concatenation can be inserted after all the internal scan segments are used up at the TOP block 101 (i.e. between BIST_SO output port 580 of TOP LTC 118 and the fromBist0 port 126 of the TAP 116). Since single chain of each ELT block is to be daisy chained, one needs to identify all the scan-in/scan-out of these ELT chains. BIST_SI input port 582 on each ELT block is the scan-in port of the ELT single chain. The scan-out port names of ELT single chains can be similarly found as well (such as ELT#_COLLAR_LBIST_SO 584). Once these ports are identified, muxes M3, M6 and M7 (556, 568, and 570, respectively) can be inserted to facilitate concatenation of single chains of all ELT blocks into the TOP single chain.

If this chip single scan chain is used for scandump purposes, and it is desired to restore the pre-scandump state of the design after scandump, the optional mux M0 572 can be used. This mux helps re-circulate the TDO 124 value back into the first flop of the single scan chain. However, if this single chain is used for automatic test pattern generation (ATPG) purposes, then the output of M0 572 may need to be intercepted by another mux so that TDI 122 can drive the first flop in the chain during ATPG. In such a case, BIST_SI 590 of the TOP LTC 118 can be the beginning of the single chain. Mux M0 572 will then need to be inserted at BIST_SI 590 of TOP LTC 118.

Accordingly, when debugging a system failure, it is desirable to be able to capture and observe the system state. This can be done by concatenating all the flip-flops in, for example, an ASIC into a single scan chain and shifting out the contents of this chain. In fact, a single scan chain on an entire IC is essential for debugging purposes and provisioning of RAS capabilities.

The foregoing description has been directed to specific embodiments. It will be apparent to those with ordinary skill in the art that modifications may be made to the described embodiments, with the attainment of all or some of the advantages. For example, the single scan chain can also be utilized for ATPG purposes. Also, even though the present invention may have been discussed with respect to a single scan chain for each ELT block, this approach is merely intended to make use of this mode to build one single scan chain for the entire chip and other configurations will become readily apparent to those with ordinary skill in the art having the benefit of teachings of the present invention. Therefore, it is the object of the appended claims to cover all such variations and modifications as come within the spirit and scope of the invention.

What is claimed is:

1. A method of providing a single scan chain of a chip, the method comprising:
selecting a TOP chain of the chip, the chip being divided into a plurality of embedded logic test (ELT) blocks;
bypassing periphery flops of the plurality of ELT blocks;
selecting a single scan chain of all ELT blocks of the chip; and
inserting the single scan chain of all ELT blocks of the chip into the TOP chain of the chip.

2. The method of claim 1 wherein the chip division is performed in a substantially hierarchical manner.

3. The method of claim 1 wherein the selecting a TOP chain is accomplished by putting the TOP chain of the chip into an internal mode.

4. The method of claim 3 wherein the TOP chain is put into internal mode by issuing an instruction to a test access port (TAP).

5. The method of claim 1 wherein a chip single chain mode is indicated by setting a user index register (IR) bit to a predefined value.

6. The method of claim 5 wherein the IR bit activates a signal sent to a test access port (TAP).

7. The method of claim 1 wherein the bypassing is accomplished by use of a plurality of multiplexers.

8. The method of claim 1 wherein the selecting a single scan chain of all ELT blocks is accomplished by putting all ELT block of the chip into an internal mode.

9. The method of claim 8 wherein the putting into internal mode is accomplished by issuing an instruction to a test access port (TAP).

10. The method of claim 1 further including selecting a plurality of blocks within a test access port (TAP) block.

11. The method of claim 10 wherein the plurality of blocks within TAP are selected from a group comprising a device identity chain block and a bypass block.

12. The method of claim 1 further including re-circulating data back to a scan chain for restoring the pre-scandump state of the chip after a scandump.

13. The method of claim 12 wherein the re-circulating is performed by utilizing a multiplexer.

14. An apparatus comprising:
a first selector to select a TOP chain of a chip, the chip being divided into a plurality of embedded logic test (ELT) blocks;
a bypassing mechanism to bypass periphery flops of the plurality of ELT blocks;
a second selector to select a single scan chain of all ELT blocks of the chip; and
a combiner to combine the single scan chain of all ELT blocks of the chip with the TOP chain of the chip,
wherein the apparatus provides a single scan chain of the chip.

15. The apparatus of claim 14 wherein the chip division is performed in a substantially hierarchical manner.

16. The apparatus of claim 14 wherein the first selector puts the TOP chain of the chip into an internal mode.

17. The apparatus of claim 16 wherein the TOP chain is put into internal mode by issuing an instruction to a test access port (TAP).

18. The apparatus of claim 14 wherein the bypassing mechanism includes a plurality of multiplexers.

19. The apparatus of claim 14 wherein the second selector puts all ELT block of the chip into an internal mode.

20. The apparatus of claim 19 wherein the putting into internal mode is accomplished by issuing an instruction to a test access port (TAP).

21. An apparatus for providing a single scan chain of a chip, the apparatus comprising:
first selection means to select a TOP chain of the chip, the chip being divided into a plurality of embedded logic test (ELT) blocks;
bypassing means for bypassing periphery flops of the plurality of ELT blocks;
second selection means to select a single scan chain of all ELT blocks of the chip; and
inserting means to insert the single scan chain of all ELT blocks of the chip into the TOP chain of the chip.

22. The apparatus of claim 21 further including a plurality of multiplexers.

23. An article of manufacture comprising:
a machine readable medium that provides instructions that, if executed by a machine, will cause the machine to perform operations including:
selecting a TOP chain of a chip, the chip being divided into a plurality of embedded logic test (ELT) blocks;
bypassing periphery flops of the plurality of ELT blocks;
selecting a single scan chain of all ELT blocks of the chip; and
inserting the single scan chain of all ELT blocks of the chip into the TOP chain of the chip,
wherein the operations provide a single scan chain of the chip.

24. The article of claim 23 wherein the chip division is performed in a substantially hierarchical manner.

25. The article of claim 23 wherein the selecting a TOP chain is accomplished by putting the TOP chain of the chip into an internal mode.

26. The article of claim 25 wherein the TOP chain is put into internal mode by issuing an instruction to a test access port (TAP) unit.

27. The article of claim 23 wherein the bypassing is accomplished by use of a plurality of multiplexer procedures.

28. The article of claim 23 wherein the selecting a single scan chain of all ELT blocks is accomplished by putting all ELT block of the chip into an internal mode.

29. The article of claim 28 wherein the putting into internal mode is accomplished by issuing an instruction to a test access port (TAP) unit.

30. The article of claim 29 wherein the operations further include selecting a plurality of blocks within a test access port (TAP) unit.

31. The article of claim 30 wherein the plurality of blocks within TAP are selected from a group comprising a device identity chain block and a bypass block.

32. The article of claim 23 wherein the operations further include re-circulating data back to a scan chain for restoring the pre-scandump state of the chip after a scandump.

33. The article of claim 32 wherein the re-circulating is performed by utilizing a multiplexer procedure.
